(19) United States
(12) Patent Application Publication
(10) Pub. No.: US 2004/0047382 A1
(43) Pub. Date: Mar. 11, 2004

(54) Semiconductor optical device and semiconductor laser module using the semiconductor optical device

(75) Inventors: Kimio Shigihara, Hyogo (JP); Kazushige Kawasaki, Hyogo (JP); Hiromasu Matsuoka, Hyogo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 10/314,966

(22) Filed: Dec. 10, 2002

(30) Foreign Application Priority Data
Sep. 5, 2002 (JP) 2002-259983

(51) Int. Cl. H01S 5/00

(52) U.S. Cl. 372/49

(57) ABSTRACT

A nonreflective film is formed with a plurality of films having refractive indices higher than 1 and formed using a high-refractive index film (first film, third film, fifth film) and a low-refractive index film (second film, fourth film, sixth film, seventh film) respectively having refractive indices higher and lower than a square root of an effective refractive index of a semiconductor laser. The plurality of films are formed so as to have at least three kinds of compositions while each film is formed with a single composition, and to bring a real part and an imaginary part of an amplitude reflectance to zero as a whole. Therefore, a semiconductor optical device which can enhance a degree of freedom in a design of the nonreflective film can be provided even when a total film thickness of the plurality of films is different from a value λ/4.

### BACKGROUND OF THE INVENTION

1. Field of the Invention

The present invention relates to a semiconductor optical device including a semiconductor optical element which emits light, and to a semiconductor laser module using the semiconductor optical device.

2. Description of the Background Art

A structure of a conventional semiconductor optical device, which is disclosed in Japanese Patent Laying-Open No. 2001-196685, will now be described with reference to FIG. 19. As shown in FIG. 19, the conventional semiconductor optical device includes a semiconductor laser 101, which is an example of the semiconductor optical element and which has an effective refractive index n_{c}, and a nonreflective film provided in contact with a light emission surface of semiconductor laser 101.

In addition, the nonreflective film includes a first film 102 provided in contact with an end surface of semiconductor laser 101 and having a refractive index n₁ and a thickness d₁, a second film 103 provided in contact with an end surface of first film 102 and having a refractive index n₂ and a thickness d₂, and a third film 104 provided in contact with an end surface of second film 103 and having a refractive index n₃ and a thickness d₃.

FIG. 20 shows wavelength dependence data of a reflectance of a nonreflective film used in a semiconductor laser having an effective refractive index n_{c}=3.2. The data shown in FIG. 20 shows wavelength dependence of the reflectance of the nonreflective film when the semiconductor laser emits light having a wavelength λ=1.3 μm.

Data 105 in FIG. 20 shows wavelength dependence of the reflectance of the nonreflective film formed with alumina having refractive index n₁=1.6 and film thickness d₁=106.2 nm, amorphous silicon having refractive index n₂=3.2 and film thickness d₂=10.6 nm, and quartz having refractive index n₃=1.45 and film thickness d₃=73.9 nm.

Data 106 in FIG. 20 shows wavelength dependence of the reflectance of the nonreflective film formed with alumina having refractive index n₁=1.6 and film thickness d₁=512.5 nm, amorphous silicon having refractive index n₂=3.2 and film thickness d₂=10.6 nm, and quartz having refractive index n₃=1.45 and film thickness d₃=73.9 nm.

When the effective refractive index of semiconductor laser 101 is n_{c}=3.2, the refractive index, which is a square root of the effective refractive index, is n_{f}=1.78885. In addition, when the light has wavelength λ=1.3 μm, a quarter of wavelength λ is 325 nm.

As shown in data 105 of the wavelength dependence, when the total film thickness of the above-mentioned three kinds of films (d₁×n₁+d₂×n₂+d₃×n₃) is nearly equal to a quarter of λ, a range of a wavelength (referred to as a “low-reflectance wavelength range” hereinafter), wherein the nonreflective film functions with a low reflectance equal to or lower than 1%, is 257 nm.

On the other hand, as shown in data 106 of the wavelength dependence, when the total film thickness of the three films (d₁×n₁+d₂×n₂+d₃×n₃) is changed to about 961 nm in order to enhance the thermal conductivity of the nonreflective film, the low-reflectance wavelength range is 78 nm.

In the conventional semiconductor optical device, the above-mentioned three kinds of films are used as the nonreflective film of the semiconductor laser as an example of the semiconductor optical element. When the total film thickness of the three films (the total sum of products of thicknesses and refractive indices of respective layers) is an integer multiple of λ/4 other than λ/4, however, the low-reflectance wavelength range becomes extremely narrower. More specifically, it is difficult to make the low-reflectance wavelength range equal to or wider than 100 nm. Therefore, in the conventional semiconductor optical device disclosed in Japanese Patent Laying-Open No. 2001-196685, the total film thickness must be equal to λ/4.

Therefore, as means to solve the above-described problem caused with the conventional semiconductor optical device disclosed in Japanese Patent Laying-Open No. 2001-196685, the inventors of the present invention are studying means for forming a nonreflective mm by a design procedure in which a real part and an imaginary part of an amplitude reflectance of two films having different compositions are respectively brought to zero, as an unpublished technique at the application of the present invention. With this design procedure, the total film thickness of two films having different compositions can be made different from λ/4.

In this design procedure, however, a degree of freedom in a design of a nonreflective film of a semiconductor optical device cannot be enhanced because only two kinds of films form the nonreflective film. With this design procedure, for example, it is impossible to provide a film which allows efficient heat radiation of a semiconductor laser as a third film in addition to the two films respectively bringing the real part and imaginary part of the amplitude reflectance to zero.

### SUMMARY OF THE INVENTION

An object of the present invention is to provide a semiconductor optical device which can enhance a degree of freedom in a design of a nonreflective film even when a total film thickness of a plurality of films is different from a value λ/4, and to provide a semiconductor laser module using the semiconductor optical device.

A semiconductor optical device according to the present invention includes a semiconductor optical element and a nonreflective film receiving light emitted from the semiconductor optical element and making incident light interfere with reflected light for light of a certain wavelength to bring a reflectance of the light to substantially zero.

In addition, the nonreflective film is formed with a plurality of films each having a refractive index higher than 1 and are formed with a high-refractive index film having a refractive index higher than a square root of an effective refractive index of the semiconductor optical element and a low-refractive index film having a refractive index lower than a square root of an effective refractive index of the semiconductor optical element.

In addition, while each of the plurality of films is formed with a single composition., the plurality of films are formed with equal to or more than three kinds of compositions, and are formed such that, a real part and an imaginary part of an amplitude reflectance are respectively brought to zero as a whole.

With the above-described structure, a design procedure can be used wherein thicknesses of respective two specific kinds of films are determined such that, a real part and an imaginary part of an amplitude reflectance of a plurality of films are respectively brought to zero as a whole, using a film of the plurality of films formed with equal to or more than three kinds of film compositions, which film is other than the aforementioned two specific kinds of films having known refractive indices and unknown thicknesses, and a film having known thickness and refractive index.

With this design procedure, a degree of freedom in a design of the nonreflective film is enhanced as compared with the procedure previously studied by the inventors of the present invention, wherein the nonreflective film is formed with two kinds of films, and is designed such that a real part and an imaginary part of an amplitude reflectance of the two films are respectively brought to zero.

A semiconductor laser module according to the present invention uses the semiconductor optical device including a semiconductor laser as the aforementioned semiconductor optical element. The semiconductor laser module includes a first reflective film having a higher reflectance than that of the nonreflective film and provided outside the semiconductor device, and a second reflective film provided on an end surface of the semiconductor device different from that end surface on which the nonreflective film is provided and having a higher reflectance than that of the nonreflective film for light of a prescribed wavelength.

In addition, light of a specific wavelength reflected from the first reflective film and the second reflective film passes through the nonreflective film. With this, the light oscillates between the first reflective film and the second reflective film.

With the above-described structure, an oscillation determined with a gain of the semiconductor laser itself and a reflectance of the nonreflective film can be suppressed utilizing the nonreflective film having a wider low-reflectance wavelength range than that of the conventional nonreflective film.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows a nonreflective film according to the present invention having a two-layer structure and having a reflectance which is brought to zero at a wavelength λ.

FIG. 2 shows a nonreflective film according to the present invention having a four-layer structure and having a reflectance which is brought to zero at wavelength λ.

FIG. 3 shows a nonreflective film of a semiconductor laser in a first embodiment.

FIG. 4 shows wavelength dependence of a reflectance of the nonreflective film of the semiconductor laser of the first embodiment.

FIG. 5 shows wavelength dependence of a reflectance of a nonreflective film of a semiconductor laser in another example of the first embodiment.

FIG. 6 shows a nonreflective film of a semiconductor laser in a second embodiment.

FIG. 7 shows wavelength dependence of a reflectance of the nonreflective film of the semiconductor laser of the second embodiment.

FIG. 8 shows wavelength dependence of a reflectance of a nonreflective film of a semiconductor laser in another example of the second embodiment.

FIG. 9 shows a nonreflective film of a semiconductor laser in a third embodiment.

FIG. 10 shows wavelength dependence of a reflectance of the nonreflective film of the semiconductor laser of the third embodiment.

FIG. 11 shows wavelength dependence of a reflectance of a nonreflective film of a semiconductor laser in another example of the third embodiment.

FIG. 12 shows a nonreflective film of a semiconductor laser in a further example of the third embodiment.

FIG. 13 shows wavelength dependence of a reflectance of the nonreflective film of the semiconductor laser of the further example of the third embodiment.

FIG. 14 shows wavelength dependence of a reflectance of a nonreflective film of another semiconductor laser of the third embodiment.

FIG. 15 shows a semiconductor laser module including a semiconductor laser having a nonreflective film of a fourth embodiment and a fiber grating.

FIG. 16 shows a relation between a gain and a loss of the semiconductor laser in the semiconductor laser module of the fourth embodiment.

FIG. 17 shows a relation between a gain and a loss of the semiconductor laser in the semiconductor laser module of the fourth embodiment in a situation wherein the gain distribution shifts to a shorter-wavelength side when a nonreflective film having a narrow low-reflectance wavelength range is used.

FIG. 18 shows a relation between a gain and a loss of the semiconductor laser in the semiconductor laser module of the fourth embodiment in a situation wherein a nonreflective film has a wide low-reflectance wavelength range.

FIG. 19 shows a nonreflective film of a conventional semiconductor optical element.

FIG. 20 shows wavelength dependence of a reflectance of the nonreflective film of the conventional semiconductor optical element.

### DESCRIPTION OF THE PREFERRED EMBODIMENTS

Semiconductor optical devices of embodiments of the present invention will be described in the following based on the drawings.

### First Embodiment

A description of “a nonreflective film having a two-layer structure which becomes nonreflective at a specific wavelength λ”, which is a base of a semiconductor optical device of this embodiment, will now be given.

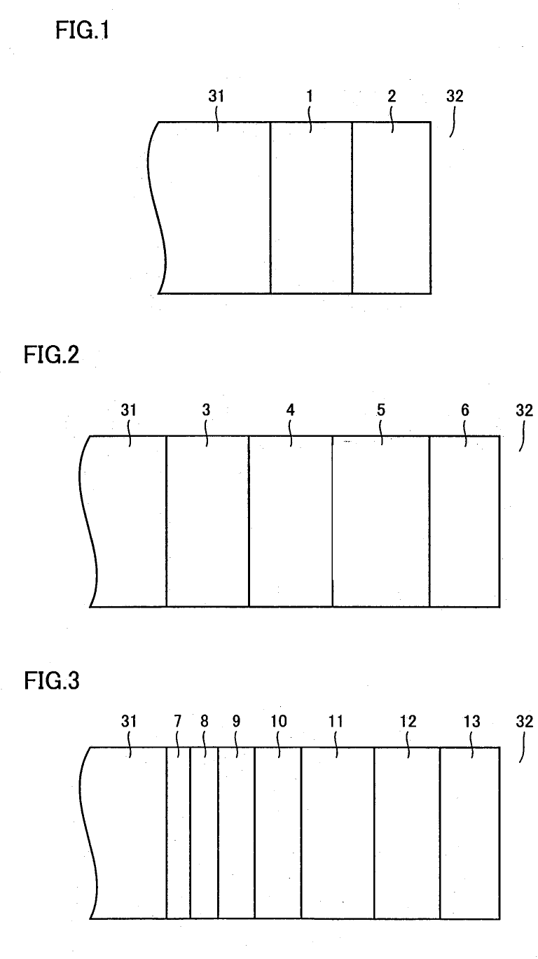

In a nonreflective film having a two-layer structure shown in FIG. 1, a two-layer structure film formed with a first film 1 having a refractive index n₁ and a thickness d₁ and a second film 2 having a refractive index n₂ and a thickness d₂, and a semiconductor laser 31 having an effective refractive index n_{c} are provided in space 32 of air, nitrogen or the like which has a refractive index of 1.

Assuming that a wavelength of light is λ and unknown phases of first film 1 and second film 2 are φ₁ and φ₂, respectively, the following equations (1a), (1b) are formulated.

$$\begin{matrix}{φ}_{1} = \frac{2 π}{λ} {n}_{1} {d}_{1} & ( 1 a ) \\ {φ}_{2} = \frac{2 π}{λ} {n}_{2} {d}_{2} & ( 1 b )\end{matrix}$$

Herein, an amplitude reflectance r is expressed as the following equation (2).

$$r = \frac{( {n}_{c} - 1 ) cos {φ}_{1} cos {φ}_{2} + ( \frac{{n}_{1}}{{n}_{2}} - \frac{{n}_{2} {n}_{c}}{{n}_{1}} ) sin {φ}_{1} sin {φ}_{2} - i \{ ( \frac{{n}_{c}}{{n}_{2}} - {n}_{2} ) cos {φ}_{1} sin {φ}_{2} + ( \frac{{n}_{c}}{{n}_{1}} - {n}_{1} ) sin {φ}_{1} cos {φ}_{2} \}}{( {n}_{c} + 1 ) cos {φ}_{1} cos {φ}_{2} - ( \frac{{n}_{2} {n}_{c}}{{n}_{1}} + \frac{{n}_{1}}{{n}_{2}} ) sin {φ}_{1} sin {φ}_{2} - i \{ ( \frac{{n}_{c}}{{n}_{2}} + {n}_{2} ) cos {φ}_{1} sin {φ}_{2} + ( \frac{{n}_{c}}{{n}_{1}} + {n}_{1} ) sin {φ}_{1} cos {φ}_{2} \}} \qquad ( 2 )$$

Respective thicknesses, d₁ and d₂ of first film 1 and second film 2, which are unknown values, are calculated for a situation when a real part and an imaginary part of amplitude reflectance r are respectively brought to zero. Inversely speaking, the film of the two-layer structure having first film 1 and second film 2 respectively having the calculated thicknesses d₁ and d₂ is a nonreflective film having an amplitude reflectance of zero.

In addition, a power reflectance R is expressed as |r|². Herein, power reflectance R is brought to zero when the following equations (3a), (3b) are satisfied.

n_{c}−1+(n₁/n₂−n₂n_{c}/n₁)tanφ₁tanφ₂=0 (3a)

(n_{c}/n₁−n₁)tanφ₁+(n_{c}/n₂−n₂)tanφ₂=0 (3b)

Assuming that, for example, effective refractive index n_{c} of semiconductor laser 31 is n_{c}=3.37, first film 1 is Ta₂O₅ (n₂=2.057), second film 2 is Al₂O₃ (n₁=1.62), and a wavelength of light is 980 nm, then the real part and imaginary part of the amplitude reflectance of the two-layer structure film formed with first film 1 and second film 2 are respectively brought to zero when thickness d₁ of first film 1 and thickness d₂ of second film 2 are 71.34 nm and 86.20 nm, respectively.

A nonreflective film of a four-layer structure, which is formed by doubling the aforementioned two-layer structure nonreflective film formed with first film 1 and second film 2, will now be described. As shown in FIG. 2, semiconductor laser 31 having effective refractive index n_{c} and a nonreflective film of a four-layer structure are provided in space 32 of air, nitrogen or the like which has a refractive index of 1.

The nonreflective film of the four-layer structure is formed with a first film 3 having refractive index n₁ and a thickness Ad₁, a second film 4 having refractive index n₂ and a thickness Ad₂, a third film 5 having refractive index n₁ and a thickness Bd₁, and a fourth film 6 having refractive index n₂ and a thickness Bd₂.

The above-mentioned values A and B are prescribed parameters. A similar procedure as described with the two-layer structure nonreflective film can be used to calculate a thickness of each film of the four-layer structure nonreflective film when the real part and imaginary part of the amplitude reflectance of the four-layer structure nonreflective film are respectively brought to zero. That is, thicknesses d₁ and d₂ when the real part and imaginary part of amplitude reflectance r are respectively brought to zero are calculated using the following equations (3c), (3d).

$$\begin{matrix}r = \frac{( {m}_{11} + {m}_{12} ) {n}_{c} - ( {m}_{21} + {m}_{22} )}{( {m}_{11} + {m}_{12} ) {n}_{c} + ( {m}_{21} + {m}_{22} )} \\ Herein , & ( 3 c ) \\ ( \begin{matrix}{m}_{11} & {m}_{12} \\ {m}_{21} & {m}_{22}\end{matrix} ) = ( \begin{matrix}cos A {φ}_{1} & - \frac{i}{{n}_{1}} sin A {φ}_{1} \\ - i {n}_{1} sin A {φ}_{1} & cos A {φ}_{1}\end{matrix} ) \times ( \begin{matrix}cos A {φ}_{2} & - \frac{i}{{n}_{2}} sin A {φ}_{2} \\ - i {n}_{2} sin A {φ}_{2} & cos A {φ}_{2}\end{matrix} ) \times \\ ( \begin{matrix}cos B {φ}_{1} & - \frac{i}{{n}_{1}} sin B {φ}_{1} \\ - i {n}_{1} sin B {φ}_{1} & cos B {φ}_{1}\end{matrix} ) \times ( \begin{matrix}cos B {φ}_{2} & - \frac{i}{{n}_{2}} sin B {φ}_{2} \\ - i {n}_{2} sin B {φ}_{2} & cos B {φ}_{2}\end{matrix} ) & ( 3 d )\end{matrix}$$

It is assumed that, for example, effective refractive index n_{c} of the semiconductor laser is n_{c}=3.37. In addition, it is assumed that first film 3 and third film 5 are respectively formed with Al₂O₃ (n₁=1.62), and second film 4 and fourth film 6 are respectively formed with Ta₂O₅ (n₂=2.057).

Furthermore, a wavelength of light is assumed to be 980 nm and, for example, the parameters are assumed to be A=1.2 and B=0.8. Amplitude reflectance r of the four-layer structure nonreflective film is brought to zero when thickness d₁ of first and third films and thickness d₂ of second and fourth films, which are unknown values, are 36.20 nm and 27.17 nm, respectively.

A nonreflective film, which is formed by adding another material having a refractive index n₃ and a film thickness d₃ to the above-described two-layer structure, will now be described. In a design of this nonreflective film, a value of thickness d₃ of another film is previously given. That is, a phase φ₃ of another material, which is expressed as equations (4), (5) shown below, is handled as a known value in the design of this nonreflective film.

Respective phases φ₁ and φ₂ of the first and second films are unknown values. For the nonreflective film formed by adding another material to the two-layer structure, thicknesses d₁ and d₂ are also calculated with a procedure similar to the design procedure of the aforementioned two-layer structure nonreflective film, that is, by respectively bringing the real part and imaginary part of amplitude reflectance r to zero.

Therefore, specific kind of another film having known refractive index and thickness is added to the specific two kinds of films having known refractive indices and unknown thicknesses, and the thicknesses of the specific two kinds of films forming the nonreflective film which brings amplitude reflectance r to about zero for specific wavelength λ are determined.

$$\begin{matrix}{φ}_{3} = \frac{2 π}{λ} {n}_{3} {d}_{3} & ( 4 ) \\ ( \begin{matrix}{m}_{11} & {m}_{12} \\ {m}_{21} & {m}_{22}\end{matrix} ) = ( \begin{matrix}cos A {φ}_{1} & - \frac{i}{{n}_{1}} sin A {φ}_{1} \\ - i {n}_{1} sin A {φ}_{1} & cos A {φ}_{1}\end{matrix} ) \times \\ ( \begin{matrix}cos A {φ}_{2} & - \frac{i}{{n}_{2}} sin A {φ}_{2} \\ - i {n}_{2} sin A {φ}_{2} & cos A {φ}_{2}\end{matrix} ) \times ( \begin{matrix}cos {φ}_{3} & - \frac{i}{{n}_{3}} sin {φ}_{3} \\ - i {n}_{3} sin {φ}_{3} & cos {φ}_{3}\end{matrix} ) & ( 5 )\end{matrix}$$

In a design procedure of a five-layer structure nonreflective film, an equation (6) is used. Thicknesses d₁ and d₂ are similarly calculated using equation (6) so as to respectively bring the real part and imaginary part of amplitude reflectance r expressed with equation (3c) to zero.

Therefore, a specific kind of film having known refractive index and thickness is added to the four-layer structure formed by doubling the specific two kinds of films having known refractive indices and unknown thicknesses, and the thicknesses of the specific two kinds of films forming the nonreflective film which brings the amplitude reflectance to about zero for specific wavelength λ are determined.

$$\begin{matrix}( \begin{matrix}{m}_{11} & {m}_{12} \\ {m}_{21} & {m}_{22}\end{matrix} ) = ( \begin{matrix}cos A {φ}_{1} & - \frac{i}{{n}_{1}} sin A {φ}_{1} \\ - i {n}_{1} sin A {φ}_{1} & cos A {φ}_{1}\end{matrix} ) \times ( \begin{matrix}cos A {φ}_{2} & - \frac{i}{{n}_{2}} sin A {φ}_{2} \\ - i {n}_{2} sin A {φ}_{2} & cos A {φ}_{2}\end{matrix} ) \times \\ ( \begin{matrix}cos B {φ}_{1} & - \frac{i}{{n}_{1}} sin B {φ}_{1} \\ - i {n}_{1} sin B {φ}_{1} & cos B {φ}_{1}\end{matrix} ) \times ( \begin{matrix}cos B {φ}_{2} & - \frac{i}{{n}_{2}} sin B {φ}_{2} \\ - i {n}_{2} sin B {φ}_{2} & cos B {φ}_{2}\end{matrix} ) \\ ( \begin{matrix}cos {φ}_{3} & - \frac{i}{{n}_{3}} sin {φ}_{3} \\ - i {n}_{3} sin {φ}_{3} & cos {φ}_{3}\end{matrix} )\end{matrix} \qquad ( 6 )$$

In a design procedure of a seven-layer structure nonreflective film, an equation (7) is used. Thicknesses d₁ and d₂ are similarly calculated using equation (7) so as to respectively bring the real part and imaginary part of amplitude reflectance r expressed with equation (3c) to zero.

Therefore, a specific kind of film having known refractive index and thickness is added to a six-layer structure formed by tripling the specific two kinds of films having known refractive indices and unknown thicknesses, and the thicknesses of the specific two kinds of films forming the nonreflective film which brings the amplitude reflectance to about zero for specific wavelength λ are determined.

$$\begin{matrix}( \begin{matrix}{m}_{11} & {m}_{12} \\ {m}_{21} & {m}_{22}\end{matrix} ) = ( \begin{matrix}cos A {φ}_{1} & - \frac{i}{{n}_{1}} sin A {φ}_{1} \\ - i {n}_{1} sin A {φ}_{1} & cos A {φ}_{1}\end{matrix} ) \times ( \begin{matrix}cos A {φ}_{2} & - \frac{i}{{n}_{2}} sin A {φ}_{2} \\ - i {n}_{2} sin A {φ}_{2} & cos A {φ}_{2}\end{matrix} ) \times \\ ( \begin{matrix}cos B {φ}_{1} & - \frac{i}{{n}_{1}} sin B {φ}_{1} \\ - i {n}_{1} sin B {φ}_{1} & cos B {φ}_{1}\end{matrix} ) \times ( \begin{matrix}cos B {φ}_{2} & - \frac{i}{{n}_{2}} sin B {φ}_{2} \\ - i {n}_{2} sin B {φ}_{2} & cos B {φ}_{2}\end{matrix} ) \times \\ ( \begin{matrix}cos C {φ}_{1} & - \frac{i}{{n}_{1}} sin C {φ}_{1} \\ - i {n}_{1} sin C {φ}_{1} & cos C {φ}_{1}\end{matrix} ) \times ( \begin{matrix}cos C {φ}_{2} & - \frac{i}{{n}_{2}} sin C {φ}_{2} \\ - i {n}_{2} sin C {φ}_{2} & cos C {φ}_{2}\end{matrix} ) \times \\ ( \begin{matrix}cos {φ}_{3} & - \frac{i}{{n}_{3}} sin {φ}_{3} \\ - i {n}_{3} sin {φ}_{3} & cos {φ}_{3}\end{matrix} )\end{matrix} \qquad ( 7 )$$

A semiconductor optical device having the seven-layer structure nonreflective film according to this embodiment will now be described.

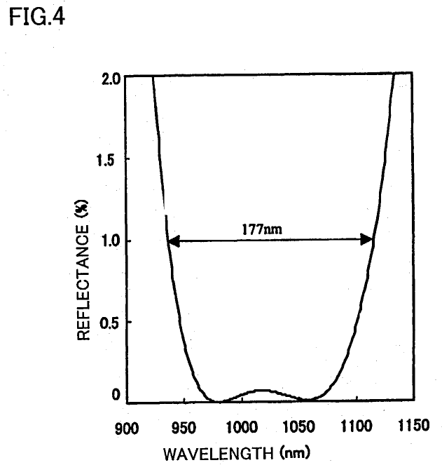

As shown in FIG. 3, the semiconductor optical device having the seven-layer structure in this embodiment is formed such that, semiconductor laser 31 and the nonreflective film formed by adding a specific kind of film having known refractive index and thickness to the six-layer structure formed by tripling the specific two kinds of films having known refractive indices and unknown thicknesses are provided in space 32 of air, nitrogen or the like which has a refractive index of 1.

The nonreflective film is formed with the six-layer structure of a first film 7 of tantalum oxide (Ta₂O₅) (refractive index n₁=2.057, thickness=Ad₁), a second film 8 of alumina (Al₂O₃) (refractive index n₂=1.62, thickness=Ad₂), a third film 9 of tantalum oxide (Ta₂O₅) (refractive index n₁=2.057, thickness=Bd₁), a fourth film 10 of alumina (Al₂O₃) (refractive index n₂=1.62, thickness=Bd₂), a fifth film 11 of tantalum oxide (Ta₂O₅) (refractive index n₁=2.057, thickness=Cd₁), and a sixth film 12 of alumina (Al₂O₃) (refractive index n₂=1.62, thickness=Cd₂), and a seventh film 13 of quartz (SiO₂) (refractive index n₃=1.45, thickness d₃=50 nm). Algebraic symbols A, B and C in the equations expressing the thicknesses represent aforementioned prescribed parameters.

According to the above-described seven-layer structure nonreflective film, the real part and imaginary part of amplitude reflectance r of the nonreflective film can respectively be brought to zero at wavelength λ=980 nm when A=2.85, B=2.0 and C=2.0, and when phases φ₁ and φ₂ of tantalum oxide and alumina are 0.485352 and 0.872841, respectively.

Herein, the thickness of each film will be as follows. First film/second film/third film/fourth film/fifth film/sixth film/seventh film=104.89 nm/239.50 nm/73.60 nm/168.07 nm/73.60 nm/168.07 nm/50 nm.

Thus, the total film thickness, which is the total sum of products of thicknesses and refractive indices of respective layers, is 1523.59 nm. This value is about 6.2 times larger than a film thickness 245 nm which is a quarter of the wavelength of light λ. The total film thickness is therefore much larger than that of the conventional semiconductor optical device.

In this situation, wavelength dependence of the reflectance of the nonreflective film is similar to a bathtub curve, as shown in FIG. 4. In addition, a low-reflectance wavelength range of the nonreflective film is 177 nm. Thus, the low-reflectance wavelength range of the nonreflective film in this embodiment is much wider than that of the conventional nonreflective film.

As described below, when a semiconductor laser and a fiber grating are combined, it is desirable to set desired wavelength λ (980 nm, for example) as the center of the bathtub curve of a reflectance distribution.

In this situation, it is preferable to set phases φ₁ and φ₂ of tantalum oxide and alumina to 0.488994 and 0.859283, respectively, and to design the nonreflective film so as to bring the reflectance to zero at wavelength λ=940 nm.

Herein, the thickness of each film is as follows. First film/second film/third film/fourth film/fifth film/sixth film/seventh film=101.36 nm/226.16 nm/71.13 nm/158.71 nm/71.13 nm/158.71 nm/50 nm.

FIG. 5 shows wavelength dependence of the reflectance of the nonreflective film when desired wavelength λ (980 nm, for example) is set as the center of the bathtub curve of the reflectance distribution. A low-reflectance wavelength range of the nonreflective film is 166 nm. Thus, the low-reflectance wavelength range of this nonreflective film is much wider than that of the conventional nonreflective film.

### Second Embodiment

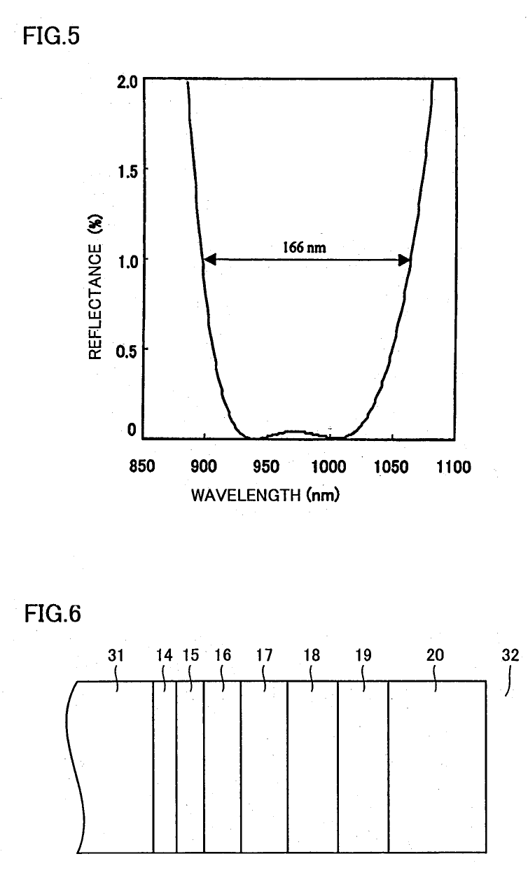

A semiconductor optical device of a second embodiment will now be described with reference to FIGS. 6-8.

The semiconductor optical device of this embodiment is formed such that, semiconductor laser 31 and a nonreflective film formed by adding a specific kind of film having known refractive index and thickness to a six-layer structure formed by tripling specific two kinds of films having known refractive indices and unknown thicknesses are provided in space 32 of air, nitrogen or the like which has a refractive index of 1.

In addition, as shown in FIG. 6, the nonreflective film includes a first film 14 of tantalum oxide (Ta₂O₅) (refractive index n₁=2.057, thickness=Ad₁), a second film 15 of alumina (Al₂O₃) (refractive index n₂=1.62, thickness=Ad₂), a third film 16 of tantalum oxide (Ta₂O₅) (refractive index n₁=2.057, thickness=Bd₁), a fourth film 17 of alumina (Al₂O₃) (refractive index n₂=1.62, thickness=Bd₂), a fifth film 18 of tantalum oxide (Ta₂O₅) (refractive index n₁=2.057, thickness=Cd₁), a sixth film 19 of alumina (Al₂O₃) (refractive index n₂=1.62, thickness=Cd₂), and a seventh film 20 of aluminum nitride (AlN) (refractive index n₃=2.072, thickness d₃=50 nm). Algebraic symbols A, B and C in the equations expressing the thicknesses represent prescribed parameters.

According to the above-described structure, the real part and imaginary part of the amplitude reflectance of the nonreflective film can respectively be brought to zero at wavelengths=980 nm when A=2.7, B=3.0 and C=2.0, and when phases φ₁ and φ₂ of tantalum oxide and alumina are 0.671597 and 0.482534, respectively.

Herein, the thickness of each film is as follows. First film/second film/third film/fourth film/fifth film/sixth film/seventh film=137.49 nm/125.44 nm/152.77 nm/139.37 nm/101.85 nm/92.92 nm/50 nm. Thus, the total film thickness is 1489.7 nm. This value is about 6.1 times larger than a value 245 nm corresponding to λ/4. The film thickness is therefore much larger than that of the conventional semiconductor optical device.

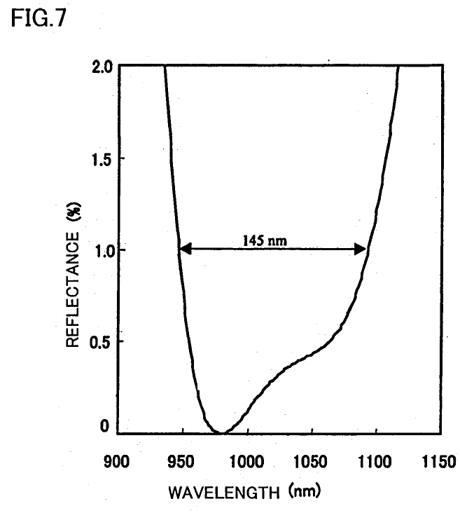

In this situation, wavelength dependence of the reflectance of the nonreflective film is similar to a bathtub curve, as shown in FIG. 7. In addition, a low-reflectance wavelength range of the nonreflective film is 145 nm. Thus, the low-reflectance wavelength range of the nonreflective film in this embodiment is much wider than that of the conventional nonreflective film.

In addition, when desired wavelength λ=980 nm is set as the center of the bathtub curve of the reflectance distribution, it is preferable to set phases φ₁ and φ₂ of tantalum oxide and alumina to 0.685788 and 0.470145, respectively, and to design the nonreflective film so as to bring the reflectance to zero at wavelength λ of 938 nm.

Herein, the thickness of each film is as follows. First film/second film/third film/fourth film/fifth film/sixth film/seventh film=134.38 nm/116.98 nm/149.31 nm/129.88 nm/99.54 nm/86.65 nm/50 nm.

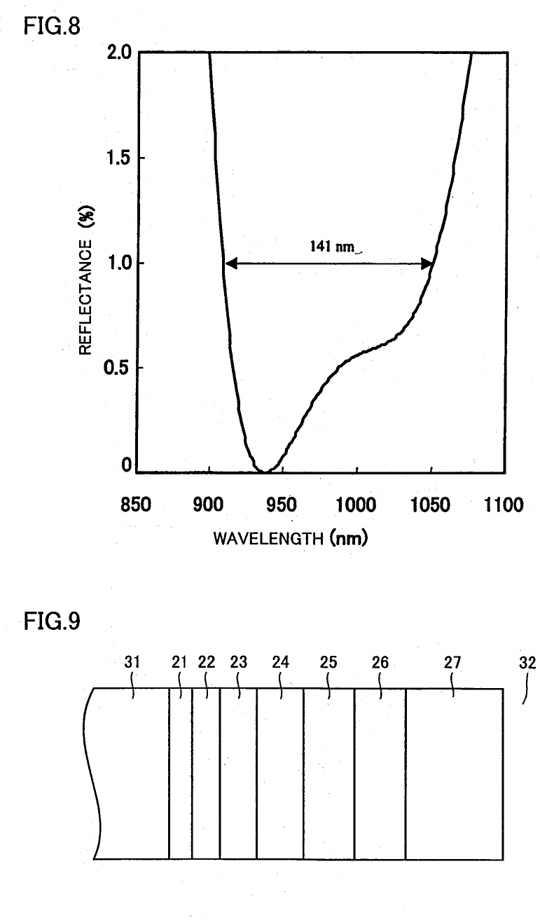

FIG. 8 shows wavelength dependence of the reflectance of the above-described nonreflective film. A low-reflectance wavelength range of this nonreflective film is 141 nm. Thus, the low-reflectance wavelength range of this nonreflective film is much wider than that of the conventional nonreflective film.

### Third Embodiment

A semiconductor optical device of a third embodiment will now be described with reference to FIGS. 9-12.

As shown in FIG. 9, the semiconductor optical device of this embodiment is formed such that, semiconductor laser 31 and a nonreflective film formed by adding a specific kind of film having known refractive index and thickness to a six-layer structure formed by tripling specific two kinds of films having known refractive indices and unknown thicknesses are provided in space 32 of air, nitrogen or the like which has a refractive index of 1.

In addition, the nonreflective film includes a first film 21 of aluminum nitride (AlN) (refractive index n₃=.2.072, thickness d₃=50 nm), a second film 22 of tantalum oxide (Ta₂O₅) (refractive index n₁=2.057, thickness=Ad₁), a third film 23 of alumina (Al₂O₃) (refractive index n₂=1.62, thickness=Ad₂), a fourth film 24 of tantalum oxide (Ta₂O₅) (refractive index n₁=2.057, thickness=Bd₁), a fifth film 25 of alumina (Al₂O₃) (refractive index n₂=1.62, thickness=Bd₂), a sixth film 26 of tantalum oxide (Ta₂O₅) (refractive index n₁=2.057, thickness=Cd₁), and a seventh film 27 of alumina (Al₂O₃) (refractive index n₂=1.62, thickness=Cd₂). The thickness of aluminum nitride (AlN) forming first film 21 is 50 nm.

Three kinds of materials, that is, aluminum nitride, tantalum oxide and alumina are used in the nonreflective film of this embodiment. The thermal conductivity of aluminum nitride is about 1.8 W/cm/° C. The thermal conductivity of tantalum oxide is about 0.1 W/cm/° C. The thermal conductivity of alumina is about 0.2 W/cm/° C. Therefore, aluminum nitride has the highest thermal conductivity in the three materials.

In addition, the real part and imaginary part of the amplitude reflectance of the nonreflective film are respectively brought to zero at wavelength λ=980 nm when A=2.0, B=2.0 and C=2.0, and when phases φ₁ and φ₂ of tantalum oxide and alumina are 0.449531 and 0.991758, respectively. Herein, the thickness of each film is as follows. First film/second film/third film/fourth film/fifth film/sixth film/seventh film=50 nm/68.17 nm/190.97 nm/68.17 nm/190.97 nm/68.17 nm/190.97 nm.

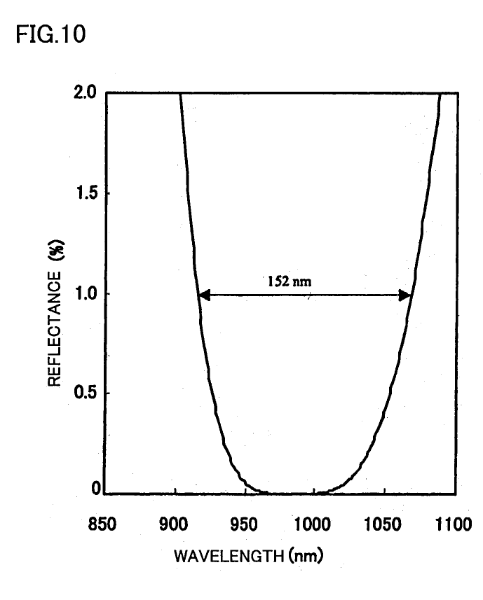

Thus, the total film thickness is 1452.26 nm. The total film thickness is about 5.9 times larger than a value 245 nm corresponding to a quarter of wavelength λ. The wavelength dependence of the reflectance of this nonreflective film is similar to a bathtub curve, as shown in FIG. 10. In addition, a low-reflectance wavelength range of the nonreflective film is 152 nm.

When desired wavelength λ=980 nm is set as the center of the bathtub curve of the reflectance distribution, it is preferable to set phases φ₁ and φ₂ of tantalum oxide and alumina to 0.449325 and 1.00016, respectively, and to design the nonreflective film so as to respectively bring the real part and imaginary part of the amplitude reflectance of the nonreflective film to zero at wavelength λ=962 nm.

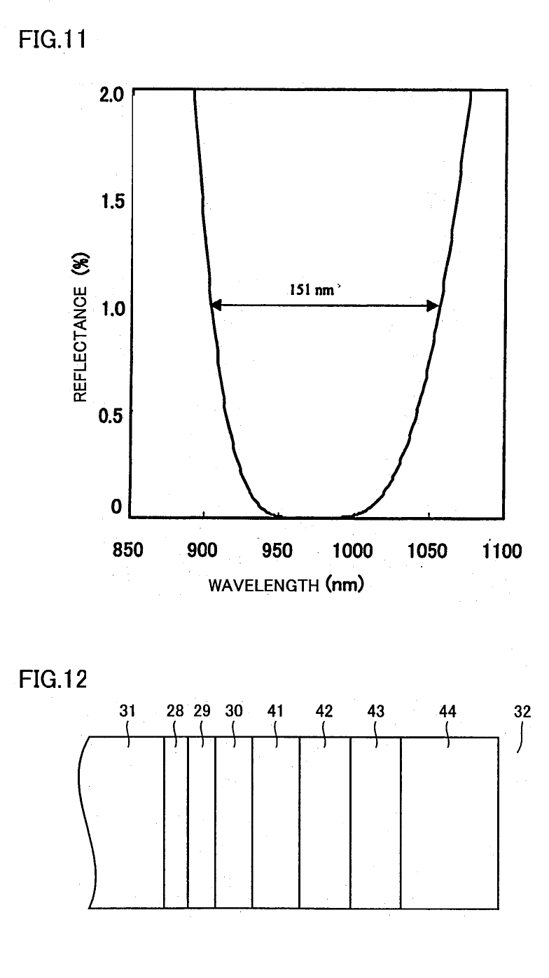

Herein, the thickness of each film is as follows. First film/second film/third film/fourth film/fifth film/sixth film/seventh film=50 nm/55.89 nm/189.05 nm/66.89 nm/189.05 nm/66.89 nm/189.05 nm. FIG. 11 shows wavelength dependence of the reflectance of this nonreflective film. A low-reflectance wavelength range of this nonreflective film is 151 nm.

FIG. 12 shows a nonreflective film including a first film of aluminum nitride (AlN) having a thickness of 120 nm.

In FIG. 12, the nonreflective film includes a first film 28 of aluminum nitride (AlN) (refractive index n₃=2.072, thickness d₃=120 nm), a second film 29 of tantalum oxide (Ta₂O₅) (refractive index n₁=2.057, thickness=Ad₁), a third film 30 of alumina (Al₂O₃) (refractive index n₂=1.62, thickness=Ad₂), a fourth film 41 of tantalum oxide (Ta₂O₅) (refractive index n₁=2.057, thickness=Bd₁), a fifth film 42 of alumina (Al₂O₃) (refractive index n₂=1.62, thickness=Bd₂), a sixth film 43 of tantalum oxide (Ta₂O₅) (refractive index n₁=2.057, thickness=Cd₁), and a seventh film 44 of alumina (Al₂O₃) (refractive index n₂=1.62, thickness=Cd₂).

In addition, the real part and imaginary part of the amplitude reflectance of the nonreflective film are respectively brought to zero at wavelength λ=980 nm when A=0.9, B=2.0 and C=2.0, and when phases φ₁ and φ₂ of tantalum oxide and alumina are 0.726468 and 0.860316, respectively.

Herein, the thickness of each film is as follows. First film/second film/third film/fourth film/fifth film/sixth film/seventh film=120 nm/49.58 nm/74.55 nm/110.17 nm/165.66 nm/110.17 nm/165.66 nm. Thus, the total film thickness of the aforementioned nonreflective film is 1461.38 nm. That is, the total film thickness is about 6.0 times larger than a value 245 nm corresponding to λ/4. The total film thickness of the nonreflective film is therefore much larger than that of the conventional nonreflective film.

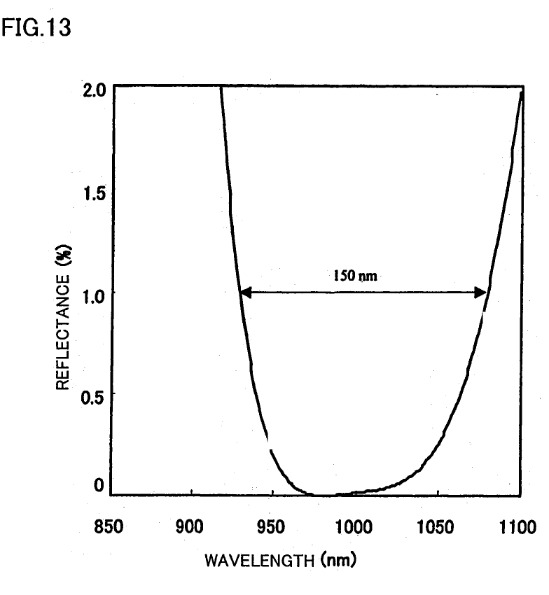

Wavelength dependence of the reflectance of this nonreflective film is similar to a bathtub curve, as shown in FIG. 13. In addition, a low-reflectance wavelength range of the nonreflective film is 150 nm. Thus, the low-reflectance wavelength range of the nonreflective film is much wider than that of the conventional nonreflective film.

When desired wavelength λ=980 nm is set as the center of the bathtub curve of the reflectance distribution, it is preferable to set phases φ₁ and φ₂ of tantalum oxide and alumina to 0.700522 and 0.891134, respectively, and to design the nonreflective film so as to bring the reflectance of the nonreflective film to zero at wavelength λ=947 nm.

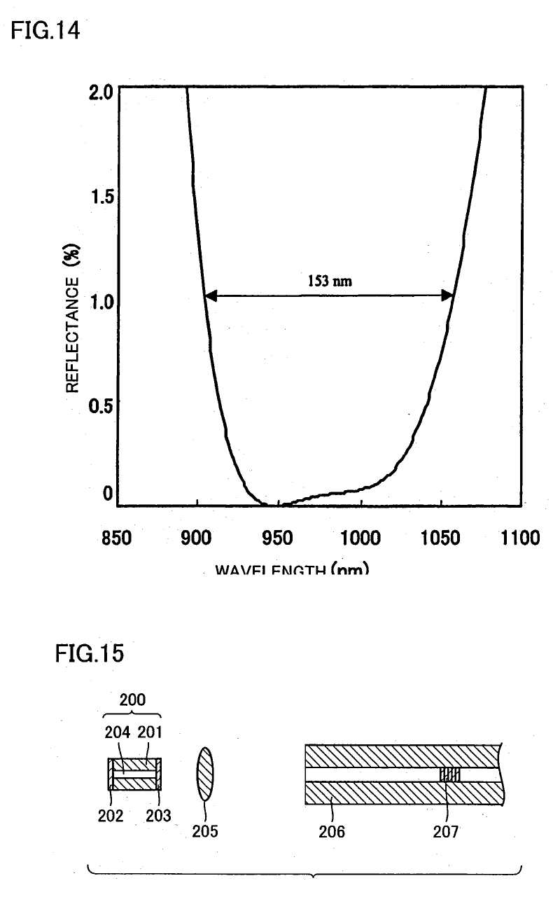

Herein, the thickness of each film is as follows. First film/second film/third film/fourth film/fifth film/sixth film/seventh film=120 nm/46.20 nm/74.62 nm/102.66 nm/165.82 nm/102.66 nm/165.82 nm. FIG. 14 shows wavelength dependence of the reflectance of this nonreflective film. A low-reflectance wavelength range of the nonreflective film is 153 nm.

Though examples of the nonreflective film of this embodiment including the first film of aluminum nitride having the thickness of 50 nm and 120 nm are shown, the thickness of aluminum nitride as the first film is not limited to these values, and a similar effect can also be obtained with other values.

The plurality of films forming each of the nonreflective film of the above-described first to third embodiments can easily make the low-reflectance wavelength range of the nonreflective film wider than that of the conventional nonreflective film using the design procedure of the nonreflective film described above, when the total sum of products of thicknesses and refractive indices of respective films is larger than a quarter of the wavelength of light emitted from the semiconductor optical laser.

In addition, as described above, it is desirable that an adjacent film of the plurality of films, which is provided adjacent to the semiconductor optical element, has a thermal conductivity higher than that of the other films. Though an example of the semiconductor device of this embodiment uses aluminum nitride as the adjacent film, this is not a limitation. A semiconductor optical device implementing an efficient heat radiation of a semiconductor laser can easily be designed using the above-described design procedure.

In addition, it is desirable that the low-reflectance wavelength range of the nonreflective film is equal to or wider than 100 nm. With this, a variation in wavelength of light emitted from the semiconductor optical element in a normal condition can flexibly be adapted.

### Fourth Embodiment

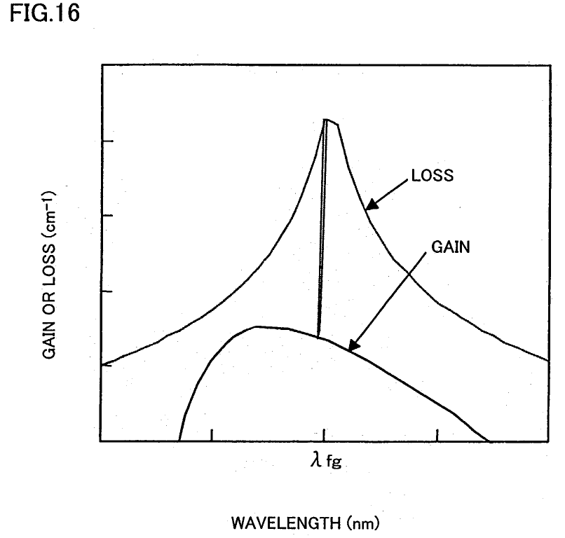

A semiconductor laser module in an embodiment according to the present invention will now be described with reference to FIGS. 15-18. A semiconductor laser module including a semiconductor laser and a fiber grating is shown in FIG. 15.

As shown in FIG. 15, the semiconductor laser module of this embodiment includes a semiconductor laser 201, a semiconductor device 200 formed with a nonreflective film 203 provided on a front end surface side of semiconductor laser 201 and having a reflectance R_{f} and a waveguide region 204 of semiconductor laser 201, a reflective film 202 provided on a rear end surface side of semiconductor laser 201 and having a reflectance Rᵣ, a lens 205 passing light emitted from waveguide region 204 therethrough, an optical fiber 206 guiding the light passing through lens 205, and a fiber grating 207 provided in a light path of optical fiber 206 and having a reflectance R_{fg}.

In the semiconductor laser module of this embodiment, fiber grating 207 is provided within optical fiber 206 to stabilize an oscillation wavelength of semiconductor laser 201. Thus, light of a specific wavelength guided into optical fiber 206 is reflected with fiber grating 207.

Nonreflective film 203 is formed with any of the nonreflective films of the first to third embodiments. Reflective film 202 is formed with a film having higher reflectance than that of nonreflective film 203. Fiber grating 207 is formed with a film having higher reflectance than that of nonreflective film 203. With this, a resonator is formed with fiber grating 207 and reflective film 202, so that light resonates between fiber grating 207 and reflective film 202. Lens 205 is provided to efficiently guide the light emitted from semiconductor laser 201 into the light path of optical fiber 206.

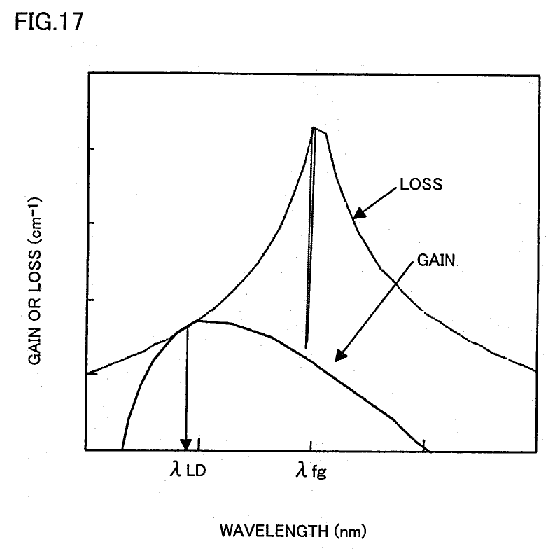

FIG. 16 shows a relation between a gain and a loss of the semiconductor laser of the semiconductor laser module of this embodiment provided with fiber grating 207. Fiber grating 207 has reflectance R_{fg} for a specific wavelength λ_{fg}. Fiber grating 207, however, has a reflectance of about zero for wavelengths other than specific wavelength λ_{fg}. Therefore, as shown in FIG. 16, the loss of the semiconductor laser becomes extremely small locally at specific wavelength λ_{fg}. Gain data shown in FIG. 16 intersects with the extremely small local portion of loss data. As a result, the semiconductor laser module usually oscillates at specific wavelength λ_{fg}.

The gain distribution of the semiconductor laser, however, shifts to a shorter-wavelength side when, for example, an ambient temperature is low. Therefore, the loss of the semiconductor laser determined with nonreflective film 203 may become smaller than the loss of the semiconductor laser determined with fiber grating 207, as shown in FIG. 17. In this situation, gain data shown in FIG. 17 intersects with a portion of loss data other than the extremely small local portion. Thus, the semiconductor laser module oscillates at a wavelength λ_{LD}, not at wavelength λ_{fg}. As a result, a side mode repression ratio, which is a ratio of the intensity of light at wavelength λ_{LD} to that at wavelength λ_{fg}, disadvantageously becomes smaller, or the semiconductor laser disadvantageously oscillates at a wavelength other than the wavelength determined with the loss of fiber grating 207 as described above.

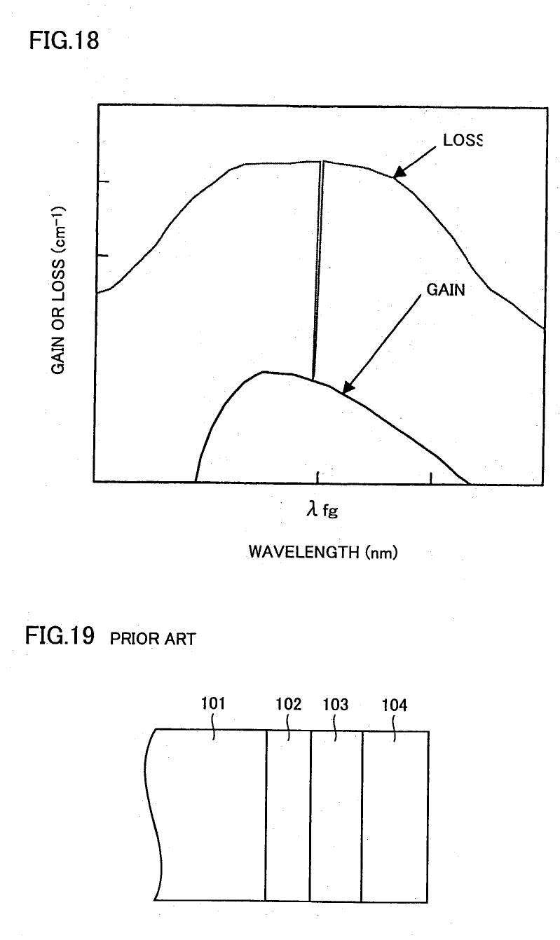

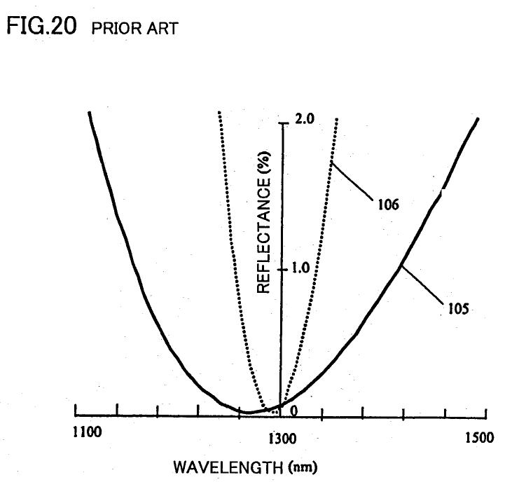

As shown in FIG. 18, in the semiconductor laser module of this embodiment, nonreflective film 203 having a low-reflectance wavelength range equal to or wider than 100 nm is provided on the front end surface side of semiconductor laser 201. Therefore, loss data shown in FIG. 18 has a gentle convex curve rather than a curve with steep slope portions as the loss data shown in FIGS. 16 and 17. As a result, the loss of the semiconductor laser determined with fiber grating 207 can be made smaller than the loss of the semiconductor laser determined with the reflectance of nonreflective film 203 at wider wavelength range. That is, gain data intersects with the extremely small local portion of loss data even when the gain distribution shifts to a shorter-wavelength side or a longer-wavelength side to some extent. Therefore, the oscillation at wavelength λ_{LD} shown in FIG. 17 can be suppressed, and the side mode suppression ratio of semiconductor laser 201 can be prevented from becoming smaller.

A seven-layer structure nonreflective film is shown as an example for each semiconductor optical device of above-described first to fourth embodiments. The structure of the nonreflective film according to the present invention, however, is not limited to the seven-layer structure, and may be a structure having any number of layers such as a nine-layer structure or an eleven-layer structure, so long as it includes a plurality of films having at least three kinds of refractive indices.

For the parameters A, B and C of each nonreflective film of the first to fourth embodiments, prescribed values are shown in each embodiment as an example. The parameters of the nonreflective film of the present invention, however, are not limited to the prescribed values used in the nonreflective film of each embodiment. Similar effects as with the nonreflective films of the first to fourth embodiments can be obtained with parameters of the nonreflective film having other values, so long as the values can respectively bring the real part and imaginary part of the amplitude reflectance to zero.

Each semiconductor optical device of the first to fourth embodiments is described with the nonreflective film formed with a plurality of films having three kinds of refractive indices as an example. Even if the plurality of films forming the nonreflective film have equal to or more than four kinds of refractive indices, however, when thicknesses of specific two kinds of films are determined so as to respectively bring the real part and imaginary part of the amplitude reflectance of the plurality of films to zero with the procedure described above, similar effects as with the nonreflective films of the first to fourth embodiments can be obtained by previously setting phase conditions, that is, thicknesses of the films other than the specific two kinds of films of the plurality of films.

Furthermore, though each example of the semiconductor optical device of the first to third embodiments uses a semiconductor laser as an example of semiconductor optical element, similar effect as that with the semiconductor laser can be obtained with a semiconductor optical element such as a semiconductor amplifier, a super luminescent diode, or a light modulator.

In addition, though each semiconductor optical device of the first to fourth embodiments uses the value near 980 nm as the wavelength of light emitted from the semiconductor optical element, the wavelength of light emitted from the semiconductor optical element is not limited to this value. Similar effects as that with the semiconductor optical devices of the first to fourth embodiments can be obtained with visible light, far infrared, infrared, or the like.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor optical device, comprising:
a semiconductor optical element; and
a nonreflective film receiving light emitted from said semiconductor optical element and making incident light interfere with reflected light for light of a certain wavelength to bring a reflectance of the light to substantially zero; wherein
said nonreflective film is formed with a plurality of films each having a refractive index higher than 1 and are formed with a high-refractive index film having a refractive index higher than a square root of an effective refractive index of said semiconductor optical element and a low-refractive index film having a refractive index lower than a square root of an effective refractive index of said semiconductor optical element, and
while each of said plurality of films is formed with a single composition, said plurality of films are formed with equal to or more than three kinds of compositions, and are formed such that a real part and an imaginary part of an amplitude reflectance are respectively brought to zero as a whole.

2. The semiconductor optical device according to claim 1, wherein
a total sum of products of respective thicknesses and refractive indices of said plurality of films is larger than a quarter of a wavelength of light emitted from said semiconductor optical element.

3. The semiconductor optical device according to claim 1, wherein
an adjacent film of said plurality of films that is provided adjacent to said semiconductor optical element has a thermal conductivity larger than that of the other films.

4. The semiconductor optical device according to claim 3, wherein
said adjacent film is made of aluminum nitride.

5. The semiconductor optical device according to claim 1, wherein
a range of a wavelength, wherein said nonreflective film functions with a low reflectance equal to or lower than 1%, is equal to or wider than 100 nm.

6. The semiconductor optical device according to claim 1, wherein
said semiconductor optical element is a semiconductor laser, a semiconductor amplifier, a super luminescent diode, or a semiconductor light modulator.

7. A semiconductor laser module, comprising:
the semiconductor optical device according to claim 1 including a semiconductor laser as said semiconductor optical element;
a first reflective film having a higher reflectance than that of said nonreflective film and provided outside said semiconductor device; and
a second reflective film provided on an end surface of said semiconductor device different from that end surface on which said nonreflective film is provided and having a higher reflectance than that of said nonreflective film for light of a prescribed wavelength; wherein
light of a specific wavelength reflected from said first reflective film and said second reflective film passes through said nonreflective film and oscillates between said first reflective film and said second reflective film.

8. The semiconductor laser module according to claim 7, wherein
said first reflective film is a fiber grating or a filter provided within an optical fiber.
